(19) United States
(12) Patent Application Publication
(10) Pub. No.: US 2016/0225415 A1
(43) Pub. Date: Aug. 4, 2016

(54) SEMICONDUCTOR DEVICE AND OPERATING METHOD THEREOF

(71) Applicant: SK hynix Inc., Gyeonggi-do (KR)

(72) Inventor: Hee Youl LEE, Gyeonggi-do (KR)

(21) Appl. No.: 14/816,905

(22) Filed: Aug. 3, 2015

(30) Foreign Application Priority Data
Feb. 3, 2015 (KR) 10-2015-0016717

(51) Int. Cl. G11C 7/00

(52) U.S. Cl. CPC G11C 7/00

(57) ABSTRACT

A method of operating a semiconductor device having memory blocks including cell strings corresponding to drain select lines, word lines, and source select lines, includes: performing an erase operation on memory cells included in a selected memory block; and simultaneously performing erase-verify operations on the memory cells included in the selected memory block, wherein positive voltages lower than preset voltages are applied to some lines among of the bit lines, the drain select lines, and the source select lines connected to the selected memory block during the erase and verification operation.

### CROSS-REFERENCE TO RELATED APPLICATION

The present application claims priority to Korean patent application number 10-2015-0016717, filed on Feb. 3, 2015, the entire disclosure of which is herein incorporated by reference in its entirety.

### BACKGROUND

1. Field of the Invention

Various embodiments of the present invention relate to a semiconductor device and an operating method thereof and, more particularly, to erase operations of a three-dimensional (3D) semiconductor device.

2. Discussion of Related Art

Semiconductor devices include a plurality of memory blocks. Each of the memory blocks includes a plurality of memory cells for storing data. Memory blocks of 3D semiconductor devices include a plurality of cell strings arranged on a substrate. The cell strings may be implemented in an “I” or “U” shape. The “I”-shaped cell strings includes memory cells connected in the shape of an “I” between bit lines and a source line, and “U”-shaped cell strings includes memory cells connected in a “U” shape between bit lines and a source line.

Erase operations of 3D semiconductor devices may be performed in single memory block units. An erase loop may include a step of decreasing a threshold voltage of the memory cells (i.e., an erase operation), a step of verifying the memory cells (i.e., an erase-verify operation), and a step of decreasing a threshold voltage distribution width of the memory cells (i.e., a soft program operation).

When erase-verifying the memory cells, a verification voltage may be applied to word lines, bit lines may be precharged, and then the state of the memory cells may be determined according to the bit line voltages that vary according to the threshold voltage of the memory cells.

### SUMMARY

Various embodiments of the present invention are directed to a semiconductor device capable of decreasing an erase operation time thereof, and an operating method thereof.

In an embodiment of the present invention, a method of operating a semiconductor device having memory blocks including cell strings corresponding to bit lines, drain select lines, word lines and source select lines, may comprise: performing an erase operation on memory cells included in a selected memory block; and simultaneously performing erase-verify operations on the memory cells included in the selected memory block, wherein positive voltages lower than preset voltages are applied to some lines among of the bit lines, the drain select lines, and the source select lines connected to the selected memory block during the erase and verification operation. In an embodiment of the present invention, a method of operating a semiconductor device having memory blocks including cell strings corresponding to bit lines, drain select lines, word lines, and source select lines, may comprise: performing an erase operation on memory cells included in a selected memory block; and performing erase-verify operations on memory cells for each group of cell strings, which is connected to the same source select line, wherein positive voltages lower than preset voltages are applied to some lines among of the bit lines, the drain select lines, and the source select lines connected to the selected memory block during the erase and verification operation.

In an embodiment of the present invention, a semiconductor device may include: a plurality of memory blocks that share bit lines and correspond to word lines, and drain and source select lines, respectively; a circuit group that performs an erase operation on a selected memory block; and a control circuit that controls the circuit group so that memory cells included in the selected memory block are erase-verified at the same time.

The foregoing summary is illustrative only and is not intended to be in any way limiting. In addition to the illustrated aspects, further aspects, embodiments, and features will become apparent after analyzing the drawings and the following detailed description.

### BRIEF DESCRIPTION OF THE DRAWINGS

The above and other features and advantages of the present invention will become more apparent to those of ordinary skill in the art by describing in detail embodiments thereof with reference to the attached drawings in which:

FIG. 1 is a block diagram illustrating a semiconductor device according to an embodiment of the present invention;

FIG. 2 is a cross-sectional view for describing a memory block shown in FIG. 1 in detail;

FIG. 3 is a layout view of a memory block for describing an erase operation according to an embodiment of the present invention;

FIG. 4 is a flowchart for describing an erase operation according to the embodiment of FIG. 3;

FIG. 5 is a layout view of a memory block for describing an erase operation according to an embodiment of the present invention;

FIG. 6 is a flowchart for describing an erase operation according to the embodiment of FIG. 5;

FIG. 7 is a block diagram illustrating a drive device according to an embodiment of the present invention;

FIG. 8 is a block diagram illustrating a memory system according to an embodiment of the present invention; and

FIG. 9 is a block diagram illustrating a computing system according to an embodiment of the present invention.

### DETAILED DESCRIPTION

Hereinafter, an embodiment of the present invention will be described with reference to the accompanying drawings in detail. However, the present invention is not limited to the embodiments disclosed below and may be implemented in various forms and the scope of the present invention is not limited to the following embodiments. Rather, the embodiments are provided to fully disclose the present invention to those skilled in the art to which the present invention pertains, and the scope of the present invention should be understood by the claims of the present invention. Throughout the disclosure, like reference numerals refer to like parts in the various figures and embodiments of the present invention.

The drawings are not necessarily to scale and, in some instances, proportions may have been exaggerated to clearly illustrate features of the embodiments. When an element is referred to as being connected or coupled to another element, it should be understood that the former can be directly connected or coupled to the latter, or electrically connected or coupled to the latter via an intervening element therebetween. Furthermore, when it is described that one “comprises” (or “includes”) or “has” some elements, it should be understood that it may comprise (or include) or have only those elements, or it may comprise (or include) or have other elements as well as those elements if there is no specific limitation. The terms of a singular form may include plural forms unless otherwise stated.

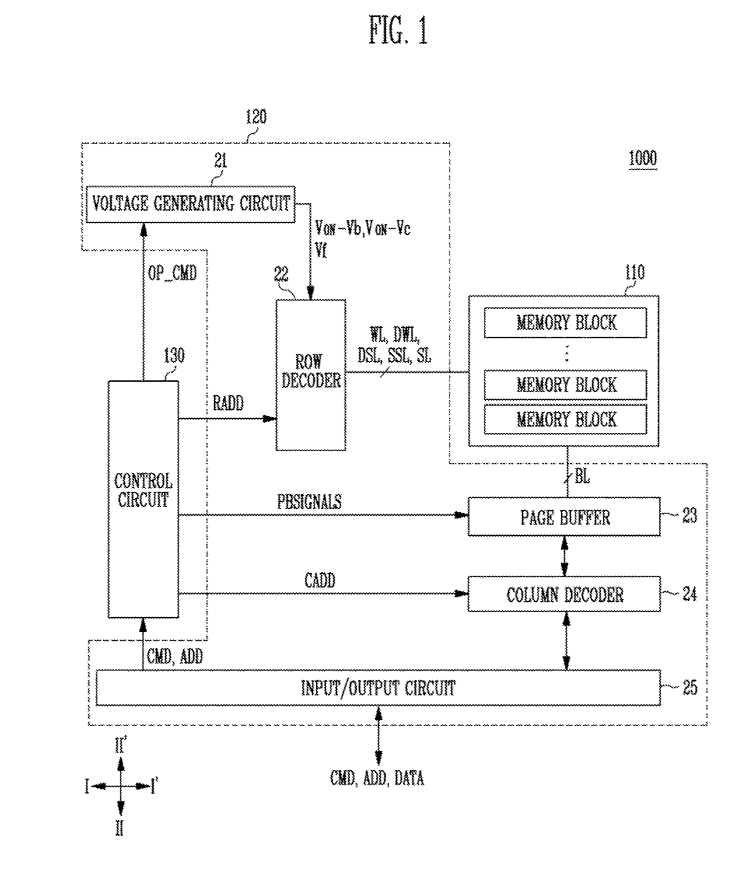

FIG. 1 is a diagram illustrating a semiconductor device 1000 according to an embodiment of the present invention.

Referring to FIG. 1, the semiconductor device 1000 may include a memory cell array 110 in which data is stored, a circuit group 120 that performs a program, read, or erase operation of the memory cell array 110, and a control circuit 130 that controls the circuit group 120.

The memory cell array 110 may include a plurality of memory blocks. Each of the memory blocks includes a plurality of cell strings. The cell strings may include a plurality of memory cells for storing data, and have a 3D structure in which the cell strings are vertically arranged on a substrate. The memory cells may be formed of single level cells (SLCs) in which data of 1 bit may be stored, or multi level cells (MLCs), triple level cells (TLCs), or quadruple level cells (QLCs) in which data of 2 bits or more may be stored. For example, the MLCs are cells in which data of 2 bits is stored in one memory cell, TLCs are cells in which data of 3 bits is stored in one memory cell, and QLCs are cells in which data of 4 bits is stored in one memory cell.

The circuit group 120 includes a voltage generating circuit 21, a row decoder 22, a page buffer 23, a column decoder 24, and an input/output circuit 25.

The voltage generating circuit 21 generates various operating voltages in response to an operation command signal OP_CMD. For example, the voltage generating circuit 21 may generate a pre-set first turn-on voltage V_{ON}, a positive second or third turn-on voltage V_{ON}−Vb or V_{ON}−Vc lower than the first turn-on voltage V_{ON}, and a verification voltage Vf. The voltage generating circuit 21 may generate various in addition to a program voltage, a pass voltage, and an erase voltage.

The row decoder 22 selects one of the memory blocks included in the memory cell array 110 in response to a row address RADD, and transmits operation voltages to word lines WLs, drain select lines DSLS, source select lines SSLs, and source lines SLs connected to the selected memory block. When dummy cells are included in the cell strings, the row decoder 22 may transmit operation voltages to dummy word lines DWLs connected to the dummy cells.

The page buffer 23 is connected with the memory blocks through bit lines BLs, transceives data with a selected memory block during the program, read, or erase operation, and temporarily stores received data. Further, the page buffer 23 precharges the bit lines BLs by applying a positive voltage lower than a preset voltage to the bit lines BLs during the erase-verify operations, and senses a voltage or a current of the bit lines BLs to which states of the memory cells are reflected. When the bit lines BLs are arranged in a first direction (I-I′), the memory blocks sharing the bit lines BLs may be arranged in a second direction (II-II′) orthogonal to the first direction (I-I′).

The column decoder 24 transceives data with the page buffer 23 in response to a column address CADD.

The input/output circuit 25 transmits a command signal CMD and an address ADD received from the outside to the control circuit 130, transmits the data DATA received from the outside to the column decoder 24, and outputs the data DATA received from the column decoder 24 to the outside or transmits the data DATA received from the column decoder 24 to the control circuit 130.

The control circuit 130 controls the circuit group 120 in response to the command signal CMD and the address ADD. To decrease an erase operation time of the selected memory cells and improve reliability of the erase operation, the control circuit 130 controls the circuit group 120, so that the memory cells of the selected memory block are simultaneously erased, and then the memory cells included in the selected memory block are simultaneously erase-verified, or are erase-verified in groups of cell strings sharing the source select line.

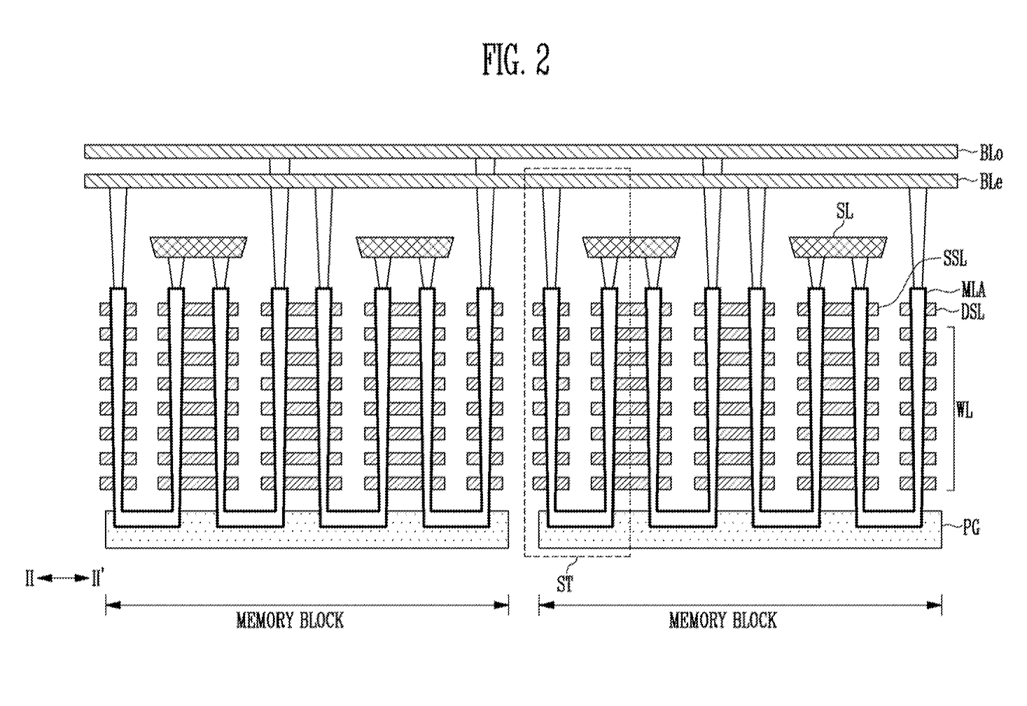

FIG. 2 is a cross-sectional view for describing the memory block shown in FIG. 1 in detail.

Referring to FIG. 2, the memory blocks have the same structure, so that only some of the memory blocks will be described as examples.

The memory block includes a plurality of cell strings STs vertically formed on a semiconductor substrate. The adjacent cell strings STs are formed in a symmetric structure. One cell string ST will be described in detail below.

The cell string ST includes a pipe gate PG formed on the substrate, memory layers MLAs vertically extended from the pipe gate PG, a plurality of word lines WLs stacked along the memory layers MLAs and spaced apart from each other, a drain select line DSL, and a source select line SSL. The memory cells are formed where the word lines WLs are in contact with the memory layers MLAs.

As illustrated in FIG. 2, in each cell string ST having a “U”-shaped structure, the memory layer MLA, in which a drain select transistor is formed, and the memory layer MLA, in which a source select transistor is formed, configure one cell string ST. The drain select transistor is formed where the memory layer MLA is in contact with the drain select line DSL, and the source select transistor is formed where the memory layer MLA is in contact with the source select line SSL. A pair of adjacent cell strings STs share the source line SL. The cell strings STs may also be implemented in various structures, in addition to the “U”-shaped structure. In the cell strings STs having the “U”-shaped structure, both the drain select transistor and the source select transistor are formed on the memory layer MLA.

Bit lines BLe and BLo are connected to the memory layers, on which the drain select transistors are formed, though plugs, and the source line SL may be connected to the memory layers, on which the source select transistors are formed, through plugs. The bit lines may be divided into even bit lines BLe and odd bit lines BLo according to an arrangement order.

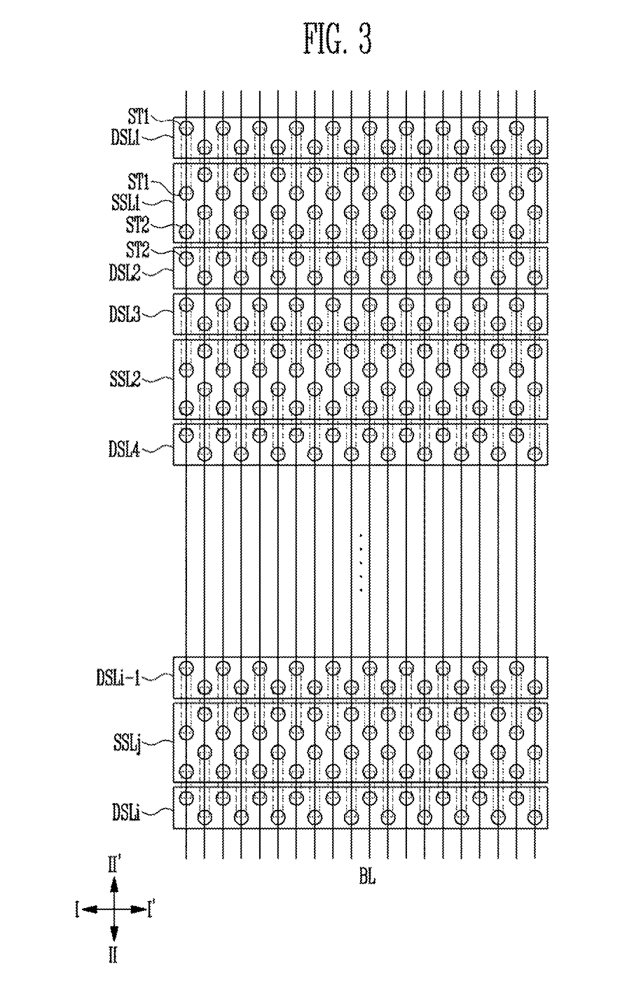

FIG. 3 is a layout view of the memory block for describing an erase operation according to an embodiment of the present invention.

Referring to FIG. 3, the memory block may include a plurality of drain select lines DLS1 to DSLi (i is a positive integer) and a plurality of source select lines SSL1 to SSLj (j is a positive integer). The source select lines SSL1 to SSLj are arranged between two drain select lines DSL1 to DSLi arranged in parallel on the same layer. For example, a first source select line SSL1 is arranged between a first drain select line DSL1 and a second drain select line DSL2. That is, two drain select lines and one source select line are paired, and a plurality of pairs is included in the memory block.

Although not illustrated in FIG. 3, a plurality of word lines is arranged under the drain select lines DSL1 to DSLi and the source select lines SSL1 to SSLj. Substrings passing through the drain select lines DLS1 to DSLi and the word lines arranged under the drain select lines DLS1 to DSLi, and substrings passing through the source select lines SSL1 to SSLj and the word lines arranged under the source select lines SSL1 to SSLj are paired to be the cell strings. For example, a substring passing through the first drain select line DSL1 and a substring passing through the first source select line SSL1 may be connected with each other to form a first cell string ST1, and another substring passing through the first source select line SSL1 and a substring passing through the second drain select line DSL2 may be connected with each other to form a second cell string ST2.

The bit lines BLs and the source lines (not shown) may be arranged on the drain select lines DSL1 to DSLi and the source select lines SSL1 to SSLj. The substrings passing through the drain select lines DSL1 to DSLi are connected to the bit lines BL, respectively, and the substrings passing through the source select lines SSL1 to SSLj are connected to the source lines (not shown), respectively.

In the erase operation according to the embodiment of FIG. 3, all of the memory cells connected to the bit lines BLs of the selected memory block are simultaneously erase-verified, thereby decreasing an erase operation time.

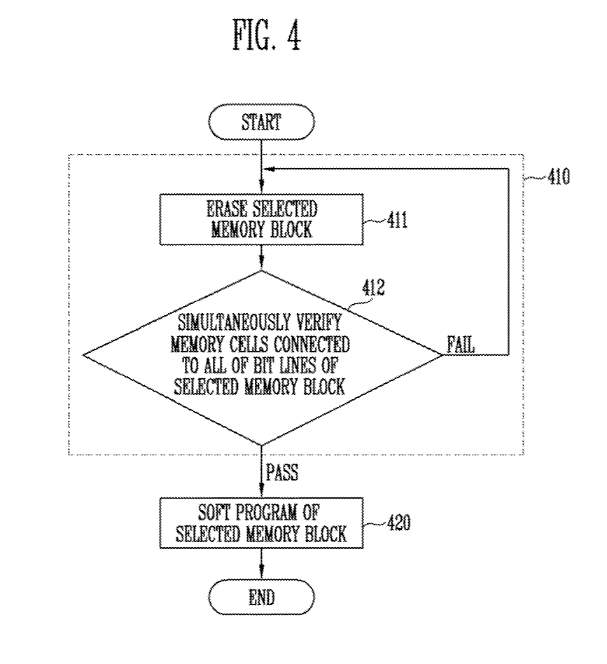

FIG. 4 is a flowchart for describing an erase operation according to the embodiment of FIG. 3.

Referring to FIG. 4, the erase operation may be performed by an incremental step pulse erase (ISPE) method. That is, the erase operation may include an erase loop 410 and a soft program loop 420. For example, the erase loop 410 erases memory cells of a selected memory cell, and the soft program loop 420 decreases a threshold voltage distribution width of the erase memory cells.

The erase loop 410 may include erasing a selected memory block (411), erase-verifying memory cells included in the selected memory block (412), and determining whether the erase operation has passed or failed (413).

In the erasing of the selected memory block (411), the memory cells included in the selected memory block are simultaneously erased by applying an erase voltage to all of the bit lines BLs connected to the selected memory block.

In the erase-verifying of the memory cells included in the selected memory block (412), the memory cells connected to all of the bit lines of the selected memory block are simultaneously verified. When all of the memory cells included in the selected memory block are simultaneously verified, a current flowing in the bit lines and the source lines may increase, so that it is possible to decrease a bit line voltage applied to the bit lines to be lower than a set voltage, decrease a verification voltage applied to the word lines to be lower than a set voltage, and decrease a turn-on voltage applied to the drain select line or the source select line to be lower than a set voltage, and thus one or more methods of the bit line voltage decrease method, the verification voltage decrease method, and the turn-on voltage decrease method may be used. When a voltage lower than the set voltage is applied only to some of the aforementioned lines, set voltages are applied to the remaining lines, respectively. Further, in addition to the aforementioned method, a method of increasing a current I-trip of the cell strings may also be used.

TABLE 1

| Line | Voltage |
|---|---|
| BL | V_{BL} or V_{BL} − Va |
| SL | 0 V or V_{SL} |
| DSL | V_{ON} or V_{ON} − Vb |
| SSL | V_{ON} or V_{ON} − Vc |
| WL | Vf or Vf − Vd |

Referring to Table 1, the erase-verify operation may include precharging the bit lines BLs and applying a source voltage to the source lines SLs, applying a verification voltage to the word lines WLs, sensing voltages of the bit lines varied according to threshold voltages of the memory cells by applying a turn-on voltage to the drain and source select lines DSL and SSL. When the bit lines BLs are precharged, a second precharge voltage (V_{BL}−Va) lower than a preset first precharge voltage V_{BL} by a first level Va may be applied to the bit lines BLs. When the turn-on voltage is applied to the drain and source select lines DSL and SSL, a second turn-on voltage V_{ON}−Vb lower than a preset first turn-on voltage V_{ON} by a second level Vb may be applied to the drain select lines DSL, and a third turn-on voltage V_{ON}−Vc lower than the preset first turn-on voltage V_{ON} by a third level Vc may be applied to the source select lines SSLs. Otherwise, the second turn-on voltage V_{ON}−Vb or the third turn-on voltage V_{ON}−Vc may be commonly applied to the drain and source select lines DSL and SSL. That is, to increase a current I-trip flowing in the cell strings, voltages applied to the bit lines BLs and the drain and source select lines DSLs and the SSLs are decreased to be lower than the preset voltages V_{BL}, V_{ON}, and Vf. The source voltage applied to the source lines SLs may be 0 V (i.e., a ground voltage) or a positive voltage V_{SL} lower than a second precharge voltage V_{BL}−Va. Further, the verification voltage applied to the word lines WL may be a voltage Vf−Vd lower than the preset voltage Vf. Otherwise, during the erase-verify operation, the set voltages V_{BL}, V_{ON}, or Vf are applied to some lines among the bit lines BLs, the word lines WLs, and the drain and source select lines DSLs and SSLs, and the voltages V_{BL}−Va, V_{ON}−Vb, V_{ON}−Vc, or Vf−Vd lower than the set voltages V_{BL}, V_{ON} or Vf may also be applied to the remaining same lines.

When the erase operation is determined to fail at step 413, step 411 is performed again. In this case, the erase voltage may be increased by a step voltage. When the erase operation is determined to pass at step 413, a soft program loop 420 of the selected memory block is performed. The soft program loop 420 is a kind of program operation performed to decrease a threshold voltage distribution width of the erased memory cells, and may be simultaneously performed on the memory cells included in the selected memory block.

As described above, it is possible to decrease an erase operation time by simultaneously erase-verifying all of the memory cells included in the selected memory block. Further, when the voltages applied to the bit lines BLs, the drain select lines DSLs, the source select lines SSLs, and the word lines WLs connected to the selected memory block are decreased to be lower than the set voltage, and the voltage applied to the source lines SLs is increased, the current I-trip flowing in the cell strings is increased, thereby improving reliability of the erase-verify operation.

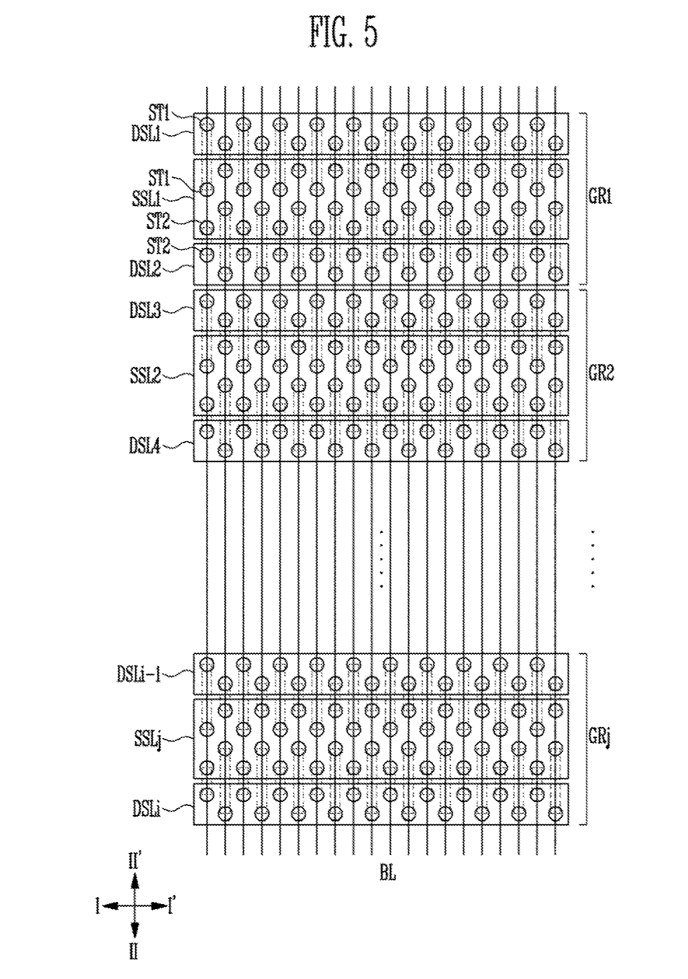

FIG. 5 is a layout view of a memory block for describing an erase operation according to an embodiment of the present invention.

Referring to FIG. 5, the memory block includes a plurality of drain select lines DLS1 to DSLi (i is a positive integer) and a plurality of source select lines SSL1 to SSLj (j is a positive integer). The source select lines SSL1 to SSLj are arranged between two drain select lines DSL1 to DSLi arranged in parallel on the same layer. For example, a first source select line SSL1 is arranged between a first drain select line DSL1 and a second drain select line DSL2. That is, two drain select lines and one source select line are paired, and a plurality of pairs is included in the memory block.

Although not illustrated in FIG. 5, a plurality of word lines is arranged under the drain select lines DSL1 to DSLi and the source select lines SSL1 to SSLj. Substrings passing through the drain select lines DLS1 to DSLi and the word lines arranged under the drain select lines DLS1 to DSLi, and substrings passing through the source select lines SSL1 to SSLj and the word lines arranged under the source select lines SSL1 to SSLj are paired to form the cell strings. For example, a substring passing through the first drain select line DSL1 and a substring passing through the first source select line SSL1 may be connected to form a first cell string ST1, and another substring passing through the first source select line SSL1 and a substring passing through the second drain select line DSL2 may be connected to form a second cell string ST2.

The bit lines BLs and the source lines (not shown) may be arranged on the drain select lines DSL1 to DSLi and the source select lines SSL1 to SSLj. The substrings passing through the drain select lines DSL1 to DSLi are connected to the bit lines BLs, respectively, and the substrings passing through the source select lines SSL1 to SSLj are connected to the source lines (not shown), respectively.

In the erase operation according to the embodiment of FIG. 5, the strings sharing the source select lines SSL1 to SSLj are grouped, and the erase-verify operation is performed on each group, so that it is possible to decrease an erase operation time compared to an erase operation performed by dividing even bit lines and odd bit lines.

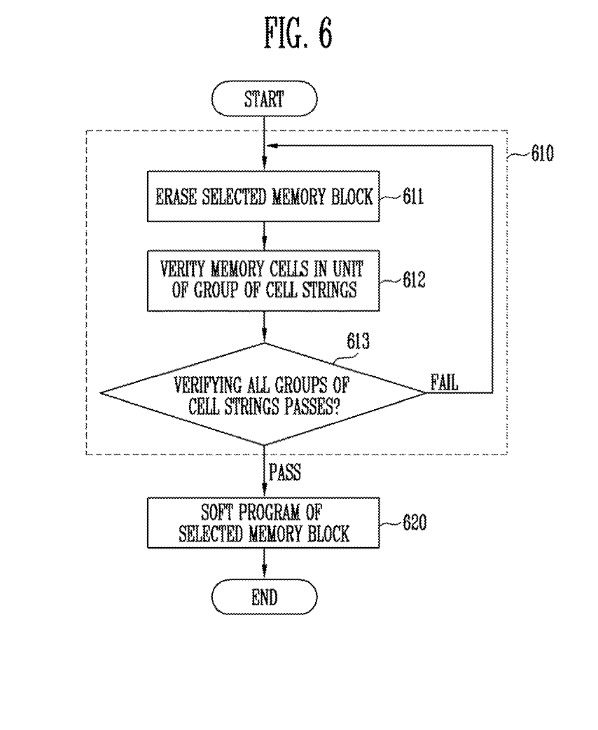

FIG. 6 is a flowchart for describing an erase operation according to the embodiment of FIG. 5.

Referring to FIG. 6, the erase operation may be performed by an incremental step pulse erase (ISPE) method. To this end, the erase operation may include an erase loop 610 and a soft program loop 620. For example, the erase loop 610 erases memory cells of a selected memory cell, and the soft program loop 620 decreases a threshold voltage distribution width of the erase memory cells.

The erase loop 610 may include erasing the selected memory block (611) and erase-verifying the memory cells included in the selected memory block groups of memory strings (612) and determining verifying all groups of cell strings passes (613).

In the erasing of the selected memory block (611), the memory cells included in the selected memory block are simultaneously erased by applying an erase voltage to all of the bit lines BLs connected to the selected memory block.

In the erase-verifying of the memory cells included in the selected memory block, the memory cells divided in groups of cell strings are verified. For example, in the erase-verifying of the memory cells (612), the memory cells included in a first string group GR1 (see FIG. 5) may be simultaneously verified, and then the memory cells included in a second string group GR2 (see FIG. 5) may be simultaneously verified, and the operation may be sequentially performed up to a j^{th} string group GRj (see FIG. 5). Here, the first string group GR1 is a group of cell strings sharing the first source select line SSL1 (see FIG. 5), the second string group GR2 is a group of cell strings sharing the second source select line SSL2 (see FIG. 5), and the j^{th} string group GRj is a group of cell strings sharing the j^{th} source select line SSLj (see FIG. 5).

When all of the memory cells included in the selected string group are simultaneously verified, current flowing in the bit lines and the source lines may increase, so that it is possible to decrease a bit line voltage applied to the bit lines to be lower than a set voltage, decrease a verification voltage applied to the word lines to be lower than a set voltage, and decrease a turn-on voltage applied to the drain select line or the source select line to be lower than a set voltage, and thus one or more methods of the bit line voltage decrease method, the verification voltage decrease method, and the turn-on voltage decrease method may be used. When a voltage lower than the set voltage is applied only to some of the aforementioned lines, set voltages are applied to the remaining lines, respectively. Further, in addition to the aforementioned method, a method of increasing a current I-trip of the cell strings may also be used.

TABLE 2

| Line | Voltage |
|---|---|
| BL | V_{BL} or V_{BL} − Va |
| SL | 0 V or V_{SL} |
| DSL | V_{ON} or V_{ON} − Vb |
| SSL | V_{ON} or V_{ON} − Vb |
| WL | Vf or Vf − Vd |

Referring to Table 2, the erase-verify operation may include precharging the bit lines BLs and applying a source voltage to the source lines SLs, applying a verification voltage to the word lines WLs, sensing voltages of the bit lines varied according to threshold voltages of the memory cells by applying a turn-on voltage to the drain and source select lines DSL and SSL. When the bit lines BLs are precharged, a second precharge voltage V_{BL}−Va lower than a preset first precharge voltage V_{BL} by a first level Va may be applied to the bit lines BLs. When the turn-on voltage is applied to the drain and source select lines DSLs and SSLs, a second turn-on voltage V_{ON}−Vb lower than a preset first turn-on voltage V_{ON} by a second level Vb may be applied to the drain select lines DSLs, and a third turn-on voltage V_{ON}−Vc lower than the preset first turn-on voltage V_{ON} by a third level Vc may be applied to the source select lines SSLs. Otherwise, the second turn-on voltage V_{ON}−Vb or the third turn-on voltage V_{ON}−Vc may be commonly applied to the drain and source select lines DSLs and SSLs. That is, to increase a current I-trip flowing in the cell strings, the voltages applied to the bit lines BLs and the drain and source select lines DSLs and the SSLs are decreased to be lower than the preset voltages V_{BL}, V_{ON}, and Vf. The source voltage applied to the source lines SLs may be 0 V (i.e., a ground voltage) or a positive voltage V_{SL} lower than a second precharge voltage V_{BL}−Va. Further, the verification voltage applied to the word lines WLs may also be a voltage Vf−Vd lower than the preset voltage Vf. Otherwise, during the erase-verify operation, the set voltages V_{BL}, V_{ON}, or Vf are applied to some lines among the bit lines BLs, the word lines WLs, and the drain and source select lines DSLs and SSLs, and the voltages V_{BL}−Va, V_{ON}−Vb, V_{ON}−Vc, or Vf−Vd lower than the set voltages V_{BL}, V_{ON} or Vf may also be applied to the remaining same lines. The word lines of the remaining non-selected string groups float while the erase-verify operation of the selected string group is performed.

As described in the embodiment of FIG. 5, when the erase-verify operation is performed in units of groups of strings, the erase-verify operations may be sequentially performed in groups of strings.

It is determined that the erase-verify operation of all groups of cell strings passes 613. For example, when the erase-verify operation of the first string group GR1 passes, the erase-verify operation of the second string group GR2 that is a next group is performed. However, when the erase-verify operation of the first string group GR1 is fails, operation 611 is performed again. When operation 611 is performed again, the erase voltage may be increased by the step voltage. That is, the erase-verify operations are sequentially performed on the first to j^{th} string groups GR1 to GRj until the string group that has a failed erase-verify operation is detected, then the erase-verify operation of a next string group is not performed, and the selected memory block is erased (611).

When all of the erase-verify operations of the first to j^{th} string groups GR1 to GRj pass, the soft program loop 620 of the selected memory block is performed. The soft program loop 620 is a program operation performed to decrease a threshold voltage distribution width of the erased memory cells, and may be simultaneously performed on the memory cells included in the selected memory block.

As described above, it is possible to decrease an erase operation time by simultaneously erase-verifying all of the memory cells included in the selected memory block. Further, when one or more voltages are applied to the bit lines BLs, the drain select lines DSLs, the source select lines SSLs, and the word lines WLs connected to the selected memory block are decreased to be lower than the set voltage, or the voltage applied to the source lines SLs is increased, the current I-trip flowing in the cell strings is increased, thereby improving reliability of the erase-verify operation.

Further, in the embodiments of FIGS. 3 and 5, the erase operation of the semiconductor device including the “U”-shaped cell strings has been described, but the present invention may be applied to a semiconductor device having a 3D structure including cell strings having an “I”-shape and various other shapes.

FIG. 7 is a block diagram illustrating a drive device 2000 according to an embodiment of the present invention.

Referring to FIG. 7, the drive device 2000 may include a host 2100 and a solid-state drive (SSD) 2200. The SSD 2200 may include an SSD controller 2210, a buffer memory 2220, and a semiconductor device 1000.

The SSD controller 2210 physically connects the host 2100 and the SSD 2200. That is, the SSD controller 2210 provides interfacing with the SSD 2200 in accordance with a bus format of the host 2100. Particularly, the SSD controller 2210 decodes a command provided from the host 2100. The SSD controller 2210 accesses the semiconductor device 1000 according to a result of the decoding. The bus format of the host 2100 may include a Universal Serial Bus (USB), a Small Computer System Interface (SCSI), PCI process, ATA, Parallel ATA (PATA), Serial ATA (SATA), and Serial Attached SCSI (SCSI).

Program data provided from the host 2100 and data read from the semiconductor device 1000 is temporarily stored in the buffer memory 2220. When data existing in the semiconductor device 1000 is cached when a read request is made from the host 2100, the buffer memory 2200 supports a cache function of directly providing the cached data to the host 2100. In general, a data transmission speed of the bus format (for example, SATA or SAS) of the host 2100 may be faster than a transmission speed of a memory channel. That is, when an interface speed of the host 2100 is faster than the transmission speed of the memory channel of the SSD 2200, it is possible to minimize degradation of performance generated due to speed differences by providing a buffer memory 2220 with large capacity. The buffer memory 2220 may be provided as a synchronous DRAM so that the SSD 2200 used as an auxiliary memory device with large capacity provides sufficient buffering.

The semiconductor device 1000 is provided as a storage medium of the SSD 2200. For example, the semiconductor device 1000 may be provided as a non-volatile memory device having large capacity storage performance as described with reference to FIG. 1, particularly a NAND-type flash memory.

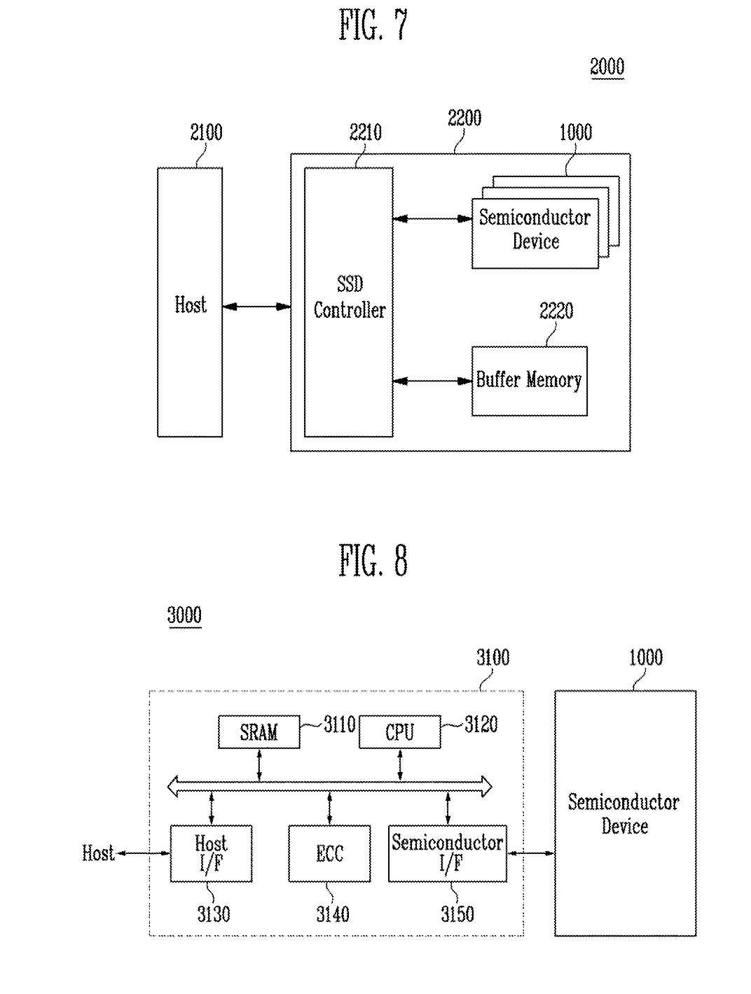

FIG. 8 is a block diagram illustrating a memory system 3000 according to an embodiment of the present invention.

Referring to FIG. 8, the memory system 3000 may include a memory controller 3100 and a semiconductor device 1000.

The semiconductor device 1000 may have a configuration substantially the same as that of FIG. 1, so that a detailed description of the semiconductor device 1000 will be omitted.

A memory controller 3100 may control the semiconductor device 1000. The SRAM 3110 may be used as a working memory of a CPU 3120. A host interface (Host I/F) 3130 may include a data exchange protocol of a host connected with the memory system 3000. An error correction circuit (ECC) 3140 provided in the memory controller 3100 may detect and correct an error included in data read from the semiconductor device 1000. A semiconductor interface (semiconductor I/F) 3150 may interface with the semiconductor device 1000. Although not illustrated in FIG. 8, the memory system 3000 may further include a ROM (not shown) for storing code data for interfacing with the host.

The memory system 3000 may be applied to one of a computer, a portable terminal, an Ultra Mobile PC (UMPC), a work station, a net-book computer, a PDA, a portable computer, a web tablet PC, a wireless phone, a mobile phone, a smart phone, a digital camera, a digital audio recorder, a digital audio player, a digital picture recorder, a digital picture player, a digital video recorder, a digital video player, a device capable of transceiving information in a wireless environment, and various devices configuring a home network.

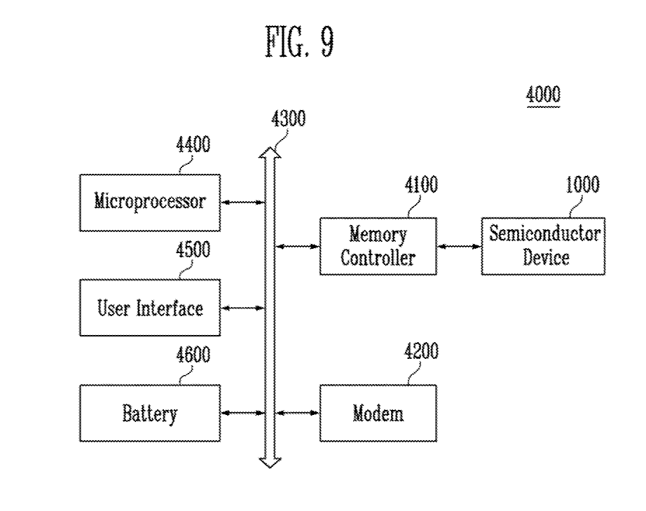

FIG. 9 is a diagram illustrating a computing system according to an embodiment of the present invention.

Referring to FIG. 9, the computing system 4000 may include a semiconductor device 1000, a memory controller 4100, a modem 4200, a microprocessor 4400, and a user interface 4500 which are electrically connected to the bus 4300. When the computing system 4000 is a mobile device, a battery 4600 for supplying an operating voltage of the computing system 4000 may be further provided. Although it is not illustrated in the drawing, the computing system 4000 may further include an application chipset, a camera image processor, a mobile DRAM, and the like.

The semiconductor device 1000 may have a configuration substantially the same as that of FIG. 1, so that a detailed description of the semiconductor device 1000 will be omitted.

The memory controller 4100 and the semiconductor device 1000 may form an SSD.

The semiconductor device and the memory controller may be embedded using various forms of package. For example, the semiconductor device and the memory controller may be embedded by using packages, such as package on package (PoP), ball grid arrays (BGAs), chip scale packages (CSPs), plastic leaded chip carrier (PLCC), plastic dual in line package (PDIP), die in waffle pack, die in wafer form, chip on board (COB), ceramic dual in line package (CERDIP), plastic metric quad flat pack (MQFP), thin quad flat pack (TQFP), small outline (SOIC), shrink small outline package (SSOP), thin small outline (TSOP), thin quad flat pack (TQFP), system in package (SIP), multi chip package (MCP), wafer-level fabricated package (WFP), and wafer-level processed stack package (WSP).

Embodiments have been disclosed in the drawings and the specification. The specific terms used herein are for the purpose of illustration, and are not intended to limit the scope of the present invention as defined in the claims. Accordingly, those skilled in the art will appreciate that various modifications and other equivalents may be made without departing from the scope and spirit of the present disclosure. Therefore, the sole technical scope of the present invention will be defined by the technical spirit of the accompanying claims.

What is claimed is:

1. A method of operating a semiconductor device having memory blocks including cell strings corresponding to bit lines, drain select lines, word lines and source select lines, the method comprising:
performing an erase operation on memory cells included in a selected memory block; and
simultaneously performing erase-verify operations on the memory cells included in the selected memory block,
wherein positive voltages lower than preset voltages are applied to some lines among of the bit lines, the drain select lines, and the source select lines connected to the selected memory block during the erase and verification operation.

2. The method of claim 1, wherein the positive voltages lower than the preset voltages are applied to one or more groups among a group including the bit lines, a group including the drain select lines, and a group including the source select lines.

3. The method of claim 1, wherein the performing of the erase-verify operation includes:
applying a first bit line voltage that is preset or a second bit line voltage that is lower than the first bit line voltage to the bit lines connected to the selected memory block;
applying a first verification voltage that is preset or a second verification voltage that is lower than the first verification voltage to the word lines connected to the selected memory block;
applying a first turn-on voltage that is preset, a second turn-on voltage or a third turn-on voltage to the drain select line and/or the source select line connected to the selected memory block, wherein the second and third turn-on voltages are lower than the first turn-on voltage; and
sensing voltages of the bit lines.

4. The method of claim 3, wherein the second bit line voltage, the second verification voltage, and the second and third turn-on voltages are higher than a ground voltage.

5. The method of claim 1, wherein a ground voltage or a positive voltage lower than a voltage to be applied to the bit lines is applied to source lines that are connected to the cell strings corresponding to the source select lines.

6. The method of claim 1, further comprising:
performing an erase operation on the memory cells again with an increased erase voltage.

7. The method of claim 1, further comprising:
performing a soft program operation on the selected memory block when the erase-verify operation passes.

8. A method of operating a semiconductor device having memory blocks including cell strings corresponding to bit lines, drain select lines, word lines, and source select lines, the method comprising:
performing an erase operation on memory cells included in a selected memory block; and
performing erase-verify operations on memory cells for each group of cell strings, which is connected to the same source select line,
wherein positive voltages lower than preset voltages are applied to some lines among of the bit lines, the drain select lines, and the source select lines connected to the selected memory block during the erase and verification operation.

9. The method of claim 8, wherein the positive voltages lower than the preset voltages are applied to one or more groups among a group including the bit lines, a group including the drain select lines, and a group including the source select lines.

10. The method of claim 8, wherein the erase-verify operations are sequentially performed in groups of cell strings.

11. The method of claim 10, wherein, when an erase-verify operation on memory cells included in a selected group of cell strings passes, memory cells included in a next group of cell strings are simultaneously erase-verified, and
when the erase-verify operation on the memory cells included in the selected group of cell strings fails, the memory cells included in the selected memory block are simultaneously erased.

12. The method of claim 8, wherein the performing of the erase-verify operations includes:
applying a first bit line voltage that is preset or a second bit line voltage that is lower than the first bit line voltage to the bit lines connected to the selected memory block;
applying a first verification voltage that is preset or a second verification voltage that is lower than the first verification voltage to the word lines connected to the selected group of cell strings;
applying a first turn-on voltage that is preset, a second turn-on voltage or a third turn-on voltage to the drain select line or a source select line connected to the selected group of cell strings, wherein the second and third turn-on voltages are lower than the first turn-on voltage; and
sensing voltages of the bit lines.

13. The method of claim 12, wherein the second bit line voltage, the second verification voltage, and the second and third turn-on voltages are higher than a ground voltage.

14. The method of claim 9, wherein a ground voltage or a positive voltage lower than a voltage to be applied to the bit lines is applied to source lines that are connected to the cell strings corresponding to the source select lines.

15. A semiconductor device, comprising:
a plurality of memory blocks that share bit lines and correspond to word lines, and drain and source select lines, respectively;
a circuit group that performs an erase operation on a selected memory block; and
a control circuit that controls the circuit group so that memory cells included in the selected memory block are simultaneously erase-verified by applying voltages lower than preset voltages to some lines among the bit lines, the word lines, and the drain and source select lines connected to the selected memory block during an erase operation of the selected memory block.

16. The semiconductor device of claim 15, wherein each of the memory blocks is connected with word lines stacked on a substrate, the drain select line and the source select line arranged on the word lines, and the bit lines and source lines arranged on the drain and source select lines.

17. The semiconductor device of claim 16, wherein substrings corresponding to the drain select line and the word lines are connected to the bit lines, and
substrings corresponding to the source select line and the word lines are connected to the source line.

18. The semiconductor device of claim 15, wherein the control circuit controls the circuit group so that a first bit line voltage that is preset or a second bit line voltage that is lower than the first bit line voltage is applied to the bit lines connected to the selected memory block, a first verification voltage that is preset or a second verification voltage that is lower than the first verification voltage is applied to the word lines connected to the selected memory block, a first turn-on voltage that is preset, a second turn-on voltage or third turn-on voltage is applied to the drain select line or the source select line connected to the selected memory block, and voltages of the bit lines are sensed when the memory cells included in the selected memory block are erase-verified, wherein the second and third turn-on voltages are lower than the first turn-on voltage.

19. The semiconductor device of claim 18, wherein the second bit line voltage, the second verification voltage, and the second and third turn-on voltages are higher than a ground voltage.

20. The semiconductor device of claim 16, wherein when the memory cells included in the selected memory block are simultaneously erase-verified, the control circuit controls the circuit group so that a ground voltage or a positive voltage lower than the voltage applied to the bit lines is applied to the source lines.
